(19) United States
(12) Patent Application Publication
(10) Pub. No.: US 2025/0349649 A1
(43) Pub. Date: Nov. 13, 2025

(54) MANUFACTURING METHOD OF SEMICONDUCTOR STRUCTURE

(71) Applicant: Taiwan Semiconductor Manufacturing Company, Ltd., Hsinchu (TW)

(72) Inventors: Ming-Hsien Lin, Hsinchu County (TW); Kun-Yen Liao, Taipei City (TW); Chia-Tien Wu, Taichung City (TW)

(73) Assignee: Taiwan Semiconductor Manufacturing Company, Ltd., Hsinchu (TW)

(21) Appl. No.: 19/277,355

(22) Filed: Jul. 22, 2025

Related U.S. Application Data
(63) Continuation of application No. 18/408,577, filed on Jan. 10, 2024.

(51) Int. Cl. H01L 23/36; H01L 21/78; H01L 23/00; H01L 23/522

(52) U.S. Cl. CPC H01L 23/36; H01L 21/78; H01L 23/5223; H01L 23/5226; H01L 23/5228; H01L 24/08; H01L 24/80; H01L 24/94; H01L 2224/08145; H01L 2224/80895; H01L 2224/80896; H01L 2224/94

(57) ABSTRACT

A semiconductor structure includes a semiconductor die having a first region and a second region is provided. The semiconductor die includes a device layer located in the second region, an insulation material extending over the first and second regions, and metallization structures embedded in the insulation material and electrically connected with the device layer. The metallization structures include passive device structures located in the first region and thermal traces located in the second region, and the passive device structures and the thermal traces include a same material and are co-levelled. The passive device structures are electrically connected with the device layer, and the thermal traces are electrically floating.

### CROSS-REFERENCE TO RELATED APPLICATION

This application is a continuation application of and claims the priority benefit of U.S. patent application Ser. No. 18/408,577, filed on Jan. 10, 2024 and now pending. The entirety of the above-mentioned patent application is hereby incorporated by reference herein and made a part of this specification.

### BACKGROUND

Smaller form factor and better reliability drive the advancing of the packaging technologies. It is a great challenge to package and integrate different types of semiconductor dies or heterogeneous chiplets with other electronic devices.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a schematic top view of an exemplary packaging component with multiple semiconductor dies in accordance with some embodiments of the present disclosure.

FIGS. 2-6 are schematic cross-sectional views and top views showing various stages of the manufacturing method for forming a semiconductor structure according to some embodiments of the present disclosure.

FIG. 7A, FIG. 8A, FIG. 7B and FIG. 8B are schematic top views and cross-sectional views showing the relative arrangement of thermal traces and heat pipes relative to the locations of the underlying heat generating spots according to embodiments of the present disclosure.

FIG. 9 illustrates a schematic cross-sectional view of an exemplary semiconductor structure in accordance with some embodiments of the present disclosure.

FIG. 10 illustrates a schematic cross-sectional view of an exemplary package structure in accordance with some embodiments of the present disclosure.

### DETAILED DESCRIPTION

The following disclosure provides many different embodiments or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

It should be appreciated that the following embodiment(s) of the present disclosure provides applicable concepts that can be embodied in a wide variety of specific contexts. The specific embodiment(s) discussed herein is merely illustrative and is related to a three-dimensional (3D) integration structure or assembly, and does not limit the scope of the present disclosure. Embodiments of the present disclosure describe the exemplary manufacturing process of 3D stacking structures and the 3D stacking structures fabricated there-from. Certain embodiments of the present disclosure are related to the 3D stacking structures formed with wafer bonding structures and stacked wafers and/or dies. Other embodiments relate to 3D integration structures or assemblies including post-passivation interconnect (PPI) structures or interposers with other electrically connected components, including wafer-to-wafer assembled structures, die-to wafer assembled structures, package-on-package assembled structures, die-to-die assembled structures, and die-to-substrate assembled structures. The wafers or dies may include one or more types of integrated circuits or electrical components on a bulk semiconductor substrate or a silicon/germanium-on-insulator substrate. The embodiments are intended to provide further explanations but are not used to limit the scope of the present disclosure.

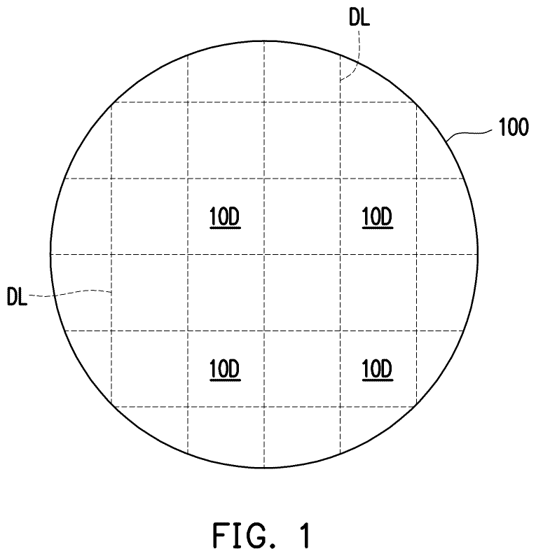

FIG. 1 is a schematic top view of an exemplary packaging component with multiple semiconductor dies in accordance with some embodiments of the present disclosure.

In FIG. 1, a packaging component is provided and may be used to form a stacking semiconductor structure or a package structure in packaging processes. In some embodiments, the packaging component is a wafer 100 with multiple semiconductor dies 10D defined or formed within. In some embodiments, the wafer 100 is a semiconductor bulk wafer with active devices and optional passive devices formed therein. As seen in FIG. 1, the dashed lines represent dicing lanes DL by which the wafer 100 will be diced in a subsequent singulation process to obtain the semiconductor dies 10D that are separated from each other through the singulation process. It is understood that the number of the semiconductor dies 10D is merely exemplary, and the semiconductor dies 10D may include the same type of dies or dies of the same functions. In some embodiments, the semiconductor dies 10D have the same design and perform the same function. In some embodiments, the semiconductor dies of the wafer 100 have different designs and perform different functions.

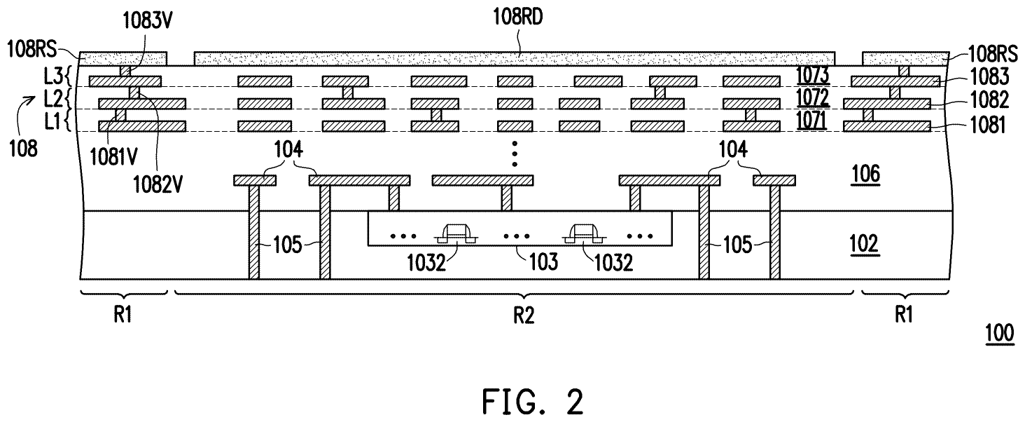

FIGS. 2-6 are schematic cross-sectional views and top views showing various stages of the manufacturing method for forming a semiconductor stacking structure according to some embodiments of the present disclosure. The same components or elements of similar or the same structure configuration(s) may be labeled with the same reference labels in the drawings.

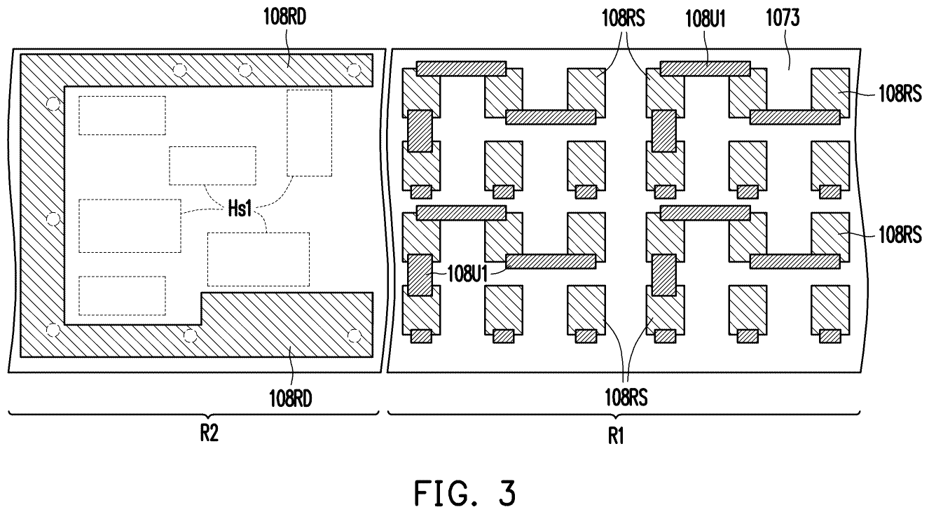

FIG. 2 is a schematic cross-sectional view showing an intermediate stage of the manufacturing method for forming a semiconductor stacking structure according to some embodiments of the present disclosure. FIG. 3 illustrates a schematic top view of one exemplary arrangement of thin resistive film structures and dummy resistive film patterns relative to the underneath element(s). In FIG. 2, in some embodiments, a wafer 100 is provided, and the wafer 100 is similar to the wafer 100 described in previous paragraph(s). In some embodiments, the wafer 100 is a semiconductor wafer, and the wafer 100 includes a semiconductor substrate 102, a device layer 103 formed in or on the semiconductor substrate 102, local connection structures 104 embedded in a dielectric material 106 formed over the semiconductor substrate 102 and connected to the device layer 103, and through vias 105 extending from the local connection structures 104 into the semiconductor substrate 102 and penetrating through the semiconductor substrate 102.

In some embodiments, the wafer 100 is a silicon wafer, or a bulk wafer made of other semiconductor materials such as III-V semiconductor materials such as gallium nitride (GaN) or gallium arsenide (GaAs). In some embodiments, the semiconductor substrate 102 may be a monocrystalline semiconductor substrate such as a silicon substrate, an elemental semiconductor such as germanium; a suitable compound semiconductor such as silicon carbide (SiC), indium arsenide (InAs), or indium phosphide (InP), or a suitable alloy semiconductor such as silicon-germanium (SiGe), gallium arsenic phosphide (GaAsP), or gallium indium phosphide (GaInP). In some embodiments, the semiconductor substrate 102 is or includes a silicon-on-insulator (SOI) substrate, silicon-germanium on insulator (SGOI) or a germanium-on-insulator (GOI) substrate. In some embodiments, the semiconductor substrate 102 includes an oxide semiconductor material such as indium tin oxide (ITO). In some embodiments, through vias 105 are or include metallic through semiconductor vias (TSVs), and the through vias 105 that are connected to the local connection structures 104 are electrically connected with some of the semiconductor devices 1032 in the device layer 103.

In certain embodiments, the device layer 103 includes semiconductor devices 1032 formed in or on the semiconductor substrate 102 of the wafer 100 during the front-end-of-line (FEOL) processes. In certain embodiments, the semiconductor devices 1032 are or include active devices such as transistors, memories or power devices. In some embodiments, the transistors include one or more types of transistors such as field effect transistors (FETs) including fin-type FETs, nanosheet FETs, nanowire FETs, gate-all-around FETs, fork-sheet FETs, or complimentary FETs, and the configurations of the transistor structures may be different depending on design requirements. In exemplary embodiments, some or all of the semiconductor devices 1032 are electrically inter-connected and electrically connected with the local connection structures 104. Herein, in the figures, the detailed configurations and interlayers may be omitted and represented by the ellipsis dots.

In some embodiments, referring to FIG. 2, only a portion of the wafer 100 is shown, and for a wafer including a plurality of dies or die units before dicing or singulation, a portion of at least one die unit of the wafer 100 is shown in FIG. 2. In some embodiments, for the die unit in the portion of the wafer 100 shown in in FIG. 2, at least a first region R1 and a second region R2 are included. In some embodiments, the second region R2 is or includes a main region formed with devices (mainly active device and optionally passive devices), and the first region R1 is or includes a peripheral region having no active devices but mainly passive devices formed therein. In one embodiment, the first region(s) R1 is located beside the second region R2. In one embodiment, the first region(s) R1 surrounds the second region R2. In some embodiments, the passive devices include capacitors, resistors, diodes, photo-diodes, sensors, inductors or fuses.

As shown in FIG. 2, in certain embodiments, an insulation material 107 and metallization structures 108 are formed over the local connection structures 104 and the dielectric material 106. In some embodiments, the metallization structures 108 are embedded in the insulation material 107 over the semiconductor substrate 102. The metallization structures 108 are electrically connected with the local connection structures 104 and are electrically connected with the device layer 103 through the local connection structures 104. In exemplary embodiments, the semiconductor devices 1032 in the device layer 103 are electrically connected with the metallization structures 108. For the semiconductor devices 1032 in the device layer 103, the metallization structures 108 and local connection structures 104 work together to provide frontside electrical connection, while the local connection structures 104 together with the through vias 105 establish backside electrical connection. In some embodiments, the local connection structures 104 and the metallization structures 108 are formed through the middle-end-of-line (MEOL) processes and the back-end-of-line (BEOL) processes respectively.

In certain embodiments, the materials of the metallization structures 108 include copper (Cu), copper alloys, titanium (Ti), tantalum (Ta), cobalt (Co), nickel (Ni), tungsten (W), nitrides thereof, or combinations thereof. In some embodiments, the metallization structures 108 including a plurality of layers of metallization structures and parts formed in-between are formed from the same metallization processes and are made of the same metal materials. In some embodiments, the metallization structures 108 are made of copper or copper alloys. In some embodiments, the materials of the insulation material 107 include silicon oxide, a spin-on dielectric material, a low-k dielectric material or a combination thereof. In some embodiments, the insulation material 107 include multiple low-k dielectric layers, and examples of low-k dielectric material include borophosporosilicate glass (BPSG), phosporosilicate glass (PSG), amorphous fluorinated carbon, parylene, BCB (bis-benzocyclobutenes), polyimide, flare, Xerogel, Aerogel, hydrogen silsesquioxane (HSQ), fluorinated silicon oxide (SiOF), or a combination thereof. In some embodiments, the insulation material 107 includes silicon oxide formed by CVD process using tetraethoxysilane (TEOS).

In some embodiments, referring to FIG. 2, the metallization structures 108 are formed in the insulation material 107, including sequentially forming first interconnect structures 1081, forming insulation layer 1071, forming second interconnect structures 1082, forming insulation layer 1072, forming third interconnect structures 1083 and forming insulation layer 1073. In some embodiments, the interconnect structures 1081, 1082, 1083 include metallic line or traces that are interconnected by metallic vias 1081V, 1082V, 1083V. From the formation sequences, the interconnect structures 1081, 1082, 1083 (along with the metallic vias 1081V, 1082V, 1083V) embedded in the insulation layers 1071, 1072, 1073 may be referred to as lower leveled interconnect structures (L1-L3) of the metallization structures 108.

In some embodiments, referring to FIG. 2, following the formation of the first, second and third interconnect structures 1081-1083 (L1-L3), thin resistive film structures 108RS and dummy resistive film patterns 108RD are simultaneously formed in the first region R1 and the second region R2 respectively, on the insulation layer 1073 and over the third interconnect structures 1083 (third level L3). The formation of the thin resistive film structures 108RS and dummy resistive film patterns 108RD involves forming a metallic resistive layer (not shown) globally over the insulation layer 1073 (all over the first region(s) R1 and the second region(s) R2) and then patterning the metallic resistive layer to form the thin resistive film structures 108RS in the first region R1 and the dummy resistive film patterns 108RD in the second region R2. As seen from FIG. 2, the thin resistive film structures 108RS in the first region R1 are physically spaced apart and separate from the dummy resistive film patterns 108RD in the second region R2. Also, the dummy resistive film patterns 108RD in the second region R2 are electrically isolated from the thin resistive film structures 108RS in the first region R1.

In some embodiments, the material of the resistive layer includes titanium nitride (TiN), Ti, tantalum nitride (TaN), Ta, W, Co, Ni, aluminum (Al), rhodium (Rh), iridium (Ir), ruthenium (Ru), molybdenum (Mo), osmium (Os), silver (Ag), or gold (Au). In some embodiments, the metallic material of the resistive layer for forming the thin resistive film structures 108RS and dummy resistive film patterns 108RD includes TiN. In some embodiments, the metallic material of the resistive layer for forming the thin resistive film structures 108RS and dummy resistive film patterns 108RD includes TaN. In some embodiments, the resistive layer is formed by performing a deposition process, a plating process or a combination thereof. The formation of the metallic resistive layer involves electrochemical plating (ECP), electroless deposition (ELD), deposition including CVD, PVD, ion beam deposition (IBD), atomic layer deposition (ALD) or other suitable process such as molecular beam epitaxy (MBE).

Referring to FIG. 3, in some embodiments, the thin resistive film structures 108RS are formed as separate rectangular blocks arranged in arrays in the first region R1. From the schematic top view of FIG. 3, the blocks of the thin resistive film structures 108RS may be interconnected by upper level interconnection structures 108U1 and/or underlying vias. Also, in FIG. 3, in some embodiments, the dummy resistive film patterns 108RD are formed as a semi-open loop band (or C-shape ring). From FIG. 3, it is seen that dummy resistive film patterns 108RD are formed as a semi-open loop surrounding potentially heat generating spots Hs1 (hot spots represented by dotted line squares) in the lower parts of the structure. It is understood that during operation, certain locations near power devices or memory devices in the second region R2 may generate heat and become the heat generating spots in the structure. The dummy resistive film patterns 108RD are arrange to be around or surround the potential heat generating spots for assisting horizontal heat transfer from the heat generating spots to the surroundings.

Referring to FIG. 2, the thin resistive film structures 108RS are electrically connected with the third interconnect structures 1083 through the vias 1083V. In some embodiments, the thin resistive film structures 108RS are electrically connected with the metallization structures 108 and are further electrically coupled with semiconductor devices 1032 or other components thorough the metallization structures 108. The thin resistive film structures 108RS include at least one high resistance metallic film to provide higher resistance and function as resistors. In some embodiments, the dummy resistive film patterns 108RD are formed in the second region R2 above the device layer 103. Referring to FIG. 2 and FIG. 3, the dummy resistive film patterns 108RD are not connected with the third interconnect structures 1083, and the dummy resistive film patterns 108RD are electrically isolated from the metallization structures 108 and are electrically floating.

In some embodiments, in the second region R2, the dummy resistive film patterns 108RD are electrically floating, even though they may be further connected with heat pipes (the locations of the later-formed heat pipes shown as elliptical or oval shaped dotted line circles). In some embodiments, the dummy resistive film patterns 108RD function as thermal elements for improving horizontal thermal conductivity and reinforcing effective thermal dissipation of the structure. As seen in FIG. 2, the dummy resistive film patterns 108RD are located at the same level with the thin resistive film structures 108RS and beside the thin resistive film structures 108RS. As the dummy resistive film patterns 108RD and the thin resistive film structures 108RS are formed of the same material from the same layer during the same process, the bottom surfaces of the dummy resistive film patterns 108RD and the thin resistive film structures 108RS are co-planar, and the dummy resistive film patterns 108RD and the thin resistive film structures 108RS are levelled with one another (co-levelled).

In some embodiments, the material of the thin resistive film structures 108RS and dummy resistive film patterns 108RD is different from the material of the metallization structures 108. Based on the embodiments, the material of the thin resistive film structures 108RS and dummy resistive film patterns 108RD has an electrical resistivity higher than that of the material of the metallization structures 108, and the material of the thin resistive film structures 108RS and dummy resistive film patterns 108RD has a thermal resistivity lower than that of the material of the insulation material 107. Thermal resistivity is the reciprocal of thermal conductivity, while electrical resistivity is the reciprocal of electrical conductivity. In some embodiments, the thin resistive film structures 108RS have higher electrical resistance than the metallization structures 108 and function as resistors. In some embodiments, the dummy resistive film patterns 108RD that are electrically floating offer higher thermal conductivity than the surrounding insulation material 107 and function as thermal traces extending horizontally over the surface(s) of the insulation layers of the insulation material 107. The thermal traces and the heat pipes are heat transfer/dissipating features or components (for thermal dissipation purposes) but are not electrically functional elements.

For the thin resistive film structures 108RS including a metallic resistive layer located on the insulator material support (rest), the resistance value (sheet resistance) of the thin film resistor may be tuned by changing the length, width and thickness of the resistor structure. For the dummy resistive film patterns 108RD including the same metallic resistive layer, the thermal resistance value of the film pattern may be tuned by changing the thickness of the metallic resistive layer. Compared with the structure without the dummy resistive film patterns (thermal traces), the formation of the dummy resistive film patterns (thermal traces) leads to about 10% to about 20% peak temperature decrease for the on-chip temperature gradient. Such temperature drop may lead to significant improvement in the reliability and performance of the devices.

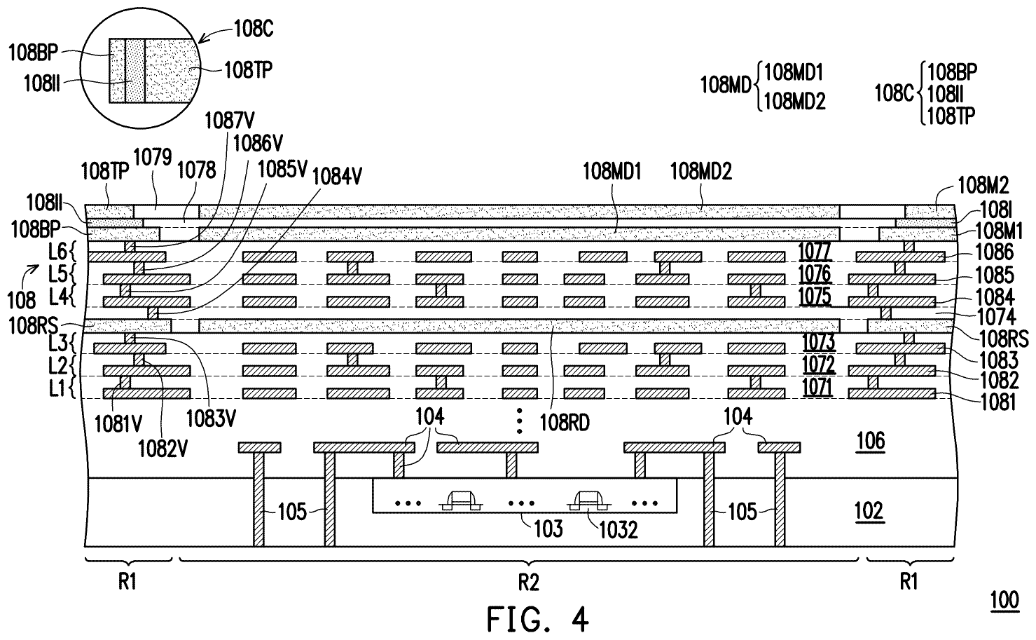

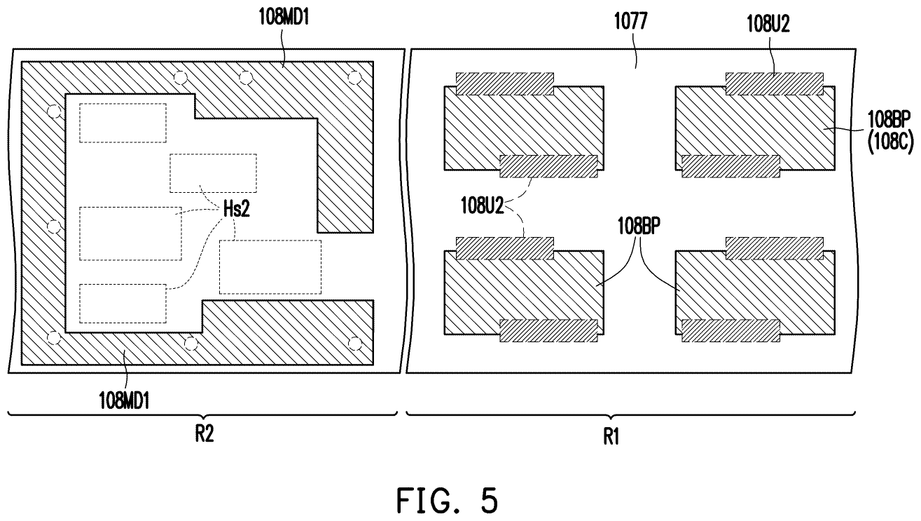

FIG. 4 is a schematic cross-sectional view showing an intermediate stage of the manufacturing method for forming a semiconductor stacking structure according to some embodiments of the present disclosure. FIG. 5 illustrates a schematic top view of one exemplary arrangement of stacked capacitor structures and dummy metallic film patterns relative to the underneath element(s).

In some embodiments, referring to FIG. 4, following the formation of the thin resistive film structures 108RS and dummy resistive film patterns 108RD, an insulation layer 1074 is formed over and covering the thin resistive film structures 108RS and dummy resistive film patterns 108RD. For example, the insulation layer 1074 fills up the spaces and gaps between the thin resistive film structures 108RS and dummy resistive film patterns 108RD. Alternatively, another insulation layer may be formed to fill up the spaces and gaps between the thin resistive film structures 108RS and dummy resistive film patterns 108RD before forming the insulation layer 1074. Later, more interconnect structures are formed in the metallization structures 108, including sequentially forming fourth interconnect structures 1084, forming insulation layer 1075, forming fifth interconnect structures 1085, forming insulation layer 1076, forming sixth interconnect structures 1086 and forming insulation layer 1077. In some embodiments, the interconnect structures 1084, 1085, 1086 include metallic line or traces that are interconnected by metallic vias 1084V-1087V. From the formation sequences, the interconnect structures 1084, 1085, 1086 (along with the metallic vias 1084V-1087V) embedded in the insulation layers 1075-1077 may be referred to as higher leveled interconnect structures (L4-L6) of the metallization structures 108.

In some embodiments, referring to FIG. 4, following the formation of the fourth, fifth and sixth interconnect structures 1084-1086 (L4-L6), stacked capacitor structures 108C and dummy metallic film patterns 108MD are formed in the first region R1 and the second region R2 respectively, on the insulation layer 1077 and over the sixth interconnect structures 1086 (sixth level L6). The formation of the stacked capacitor structures 108C and dummy metallic film patterns 108MD involves sequentially forming a first metallic layer 108M1 and an insulator layer 1081 globally over the insulation layer 1077 (all over the first region(s) R1 and the second region(s) R2), patterning the first metallic layer 108M1 and the insulator layer 1081, and forming insulation layer 1078. Later, a second metallic layer 108M2 is formed and patterned, and then insulation layer 1079 is formed. Through the patterning processes, the first metallic layer 108M1 is patterned to form first dummy metallic film patterns 108MD1 in the second region R2, and the first metallic layer 108M1 remained in the first region R1 becomes bottom plates 108BP of the stacked capacitor structures 108C. Through the patterning processes, the insulator layer 1081 is patterned to form insulator blocks 10811 in the first region(s) R1, while the insulator layer 1081 in the second region(s) R2 is fully removed, and the insulation layer 1078 fills up the gaps and space between the first dummy metallic film patterns 108MD1 and the bottom plates 108BP and between the insulator blocks 10811. Though patterning processes, the second metallic layer 108M2 is patterned to form second dummy metallic film patterns 108MD2 in the second region R2, and the second metallic layer 108M2 remained in the first region R1 becomes top plates 108TP of the stacked capacitor structures 108C.

Referring to the upper left part of FIG. 4, an exemplary partial top view of the stacked capacitor structure 108C is shown, the span of the top plate 108TP is smaller but fully overlapped with the span of the insulator block 10811, and the top plate 108TP partially covers the insulator block 10811. Similarly, referring to the exemplary partial top view shown at the upper left part of FIG. 4, the span of the insulator block 10811 is smaller but fully overlapped with the span of the bottom plate 108BP, the span of the top plate 108TP is fully overlapped with the bottom plate 108BP, and the insulator block 10811 partially covers the bottom plate 108BP.

In some embodiments, in the first region(s) R1, the bottom plate 108BP, the top plate 108TP and the insulator blocks 10811 sandwiched between the top and bottom plates 108TP, 108BP form the stacked capacitor structure 108C. In some embodiments, in the second region(s) R2, the horizontally extending first and second dummy metallic film patterns 108MD1 and 108MD2 that are separated by the insulation layer 1078 together form the dummy metallic film patterns 108MD. In some embodiments, referring to FIG. 4, the spans of the first and second dummy metallic film patterns 108MD1, 108MD2 are fully overlapped (i.e. vertical projections of the first and second dummy metallic film patterns onto the underlying plane are overlapped). In some embodiments, the first and second dummy metallic film patterns 108MD1, 108MD2 are vertically aligned. As seen from FIG. 4, the stacked capacitor structures 108C in the first region R1 are physically spaced apart and separate from the dummy metallic film patterns 108MD in the second region R2. Also, the dummy metallic film patterns 108MD in the second region R2 are electrically isolated from the stacked capacitor structures 108C in the first region R1.

Referring to FIG. 4, the stacked capacitor structures 108C are electrically connected with the below interconnect structures (e.g. sixth interconnect structure 1086 through the vias 1087V). In some embodiments, the stacked capacitor structures 108C are electrically connected with the metallization structures 108 and are further electrically coupled with semiconductor devices 1032 or other components thorough the metallization structures 108. The stacked capacitor structures 108C include metal-insulator-metal capacitors and functions as capacitors in the electrical path (in the circuits). In some embodiments, the dummy metallic film patterns 108MD are formed in the second region R2 above the device layer 103. Referring to FIG. 4, the dummy metallic film patterns 108MD are electrically isolated from the metallization structures 108, are not connected with any other electrical elements and are electrically floating (not being a part of the electrical pathway).

As the first dummy metallic film patterns 108MD1 and the base plates 108BP are formed from the same layer in the same process, the bottom surfaces of the first dummy metallic film patterns 108MD1 and the base plates 108BP are co-planar, and the first dummy metallic film patterns 108MD1 and the base plates 108BP are levelled with one another (co-levelled). Similarly, the second dummy metallic film patterns 108MD2 and the top plates 108TP are formed from the same layer in the same process, their bottom surfaces are co-planar and levelled with one another (co-levelled). As seen in FIG. 4, the dummy metallic film patterns 108MD are located beside and located at the same level with the stacked capacitor structures 108C.

In some embodiments, the material of the first metallic layer 108M1 or second metallic layer 108M2 is individually selected from TiN, Ti, TaN, Ta, W, Co, Ni, Al, Rh, Ir, Ru, Mo, Os, Ag, or Au. In some embodiments, the metallic material of the first metallic layer 108M1 includes TiN or TaN. In some embodiments, the metallic material of the second metallic layer 108M2 includes TaN or TiN. In some embodiments, the first metallic layer 108M1 or second metallic layer 108M2 is formed by performing a deposition process, a plating process or a combination thereof. The formation of the first metallic layer 108M1 or second metallic layer 108M2 involves ECP, ELD, CVD, PVD, ion beam deposition (IBD), ALD or other suitable process such as molecular beam epitaxy (MBE). In some embodiments, the material of the first metallic layer 108M1 and the material of the second metallic layer 108M2 are different. In some embodiments, the material of the first metallic layer 108M1 and the material of the second metallic layer 108M2 are substantially the same.

In some embodiments, the materials of the first metallic layer 108M1 and second metallic layer 108M2 are different from the material of the metallization structures 108. In certain embodiments, relative to the insulation material 107, the first metallic layer 108M1 has higher thermal conductivity, and the second metallic layer 108M2 has higher thermal conductivity, so that the first and second dummy metallic patterns 108MD1 and 108MD2 are thermal traces.

Referring to FIG. 5, in some embodiments, the bottom plates 108BP of the stacked capacitor structures 108C are formed as separate rectangular metallic blocks arranged side by side or in arrays in the first region R1. From the schematic top view of FIG. 5, the blocks of the bottom plates 108BP may be interconnected by upper level interconnection structures 108U2 and/or underlying vias. In the second region R2, as seen in FIG. 5, in some embodiments, the first dummy metallic film pattern 108MD1 is formed as a partial-open loop band. From FIG. 5, it is seen that first dummy metallic film pattern 108MD1 is formed as an integral open loop surrounding potential heat generating spots Hs2 (hot spots represented by dotted line squares) in the lower parts of the structure. The dummy metallic film patterns 108MD are arrange to be around or surround the potential heat generating spots for assisting horizontal heat transfer from the heat generating spots to the surroundings.

In some embodiments, in the second region R2, the electrically floating first dummy metallic film patterns 108MD1 and second dummy metallic film patterns 108MD2 are further connected with heat pipes (the locations of the later-formed heat pipes shown as elliptical or oval shaped dotted line circles in FIG. 5). In some embodiments, the dummy metallic film patterns 108MD that are made of highly thermal conductivity materials offer higher thermal conductivity than the surrounding insulation material 107 and function as thermal traces. The thermal traces are heat transfer/dissipating features or components (for thermal dissipation purposes) but are not electrically functional elements. In some embodiments, the dummy metallic film patterns 108MD function as thermal traces for improving horizontal thermal conductivity and reinforcing effective thermal dissipation of the structure.

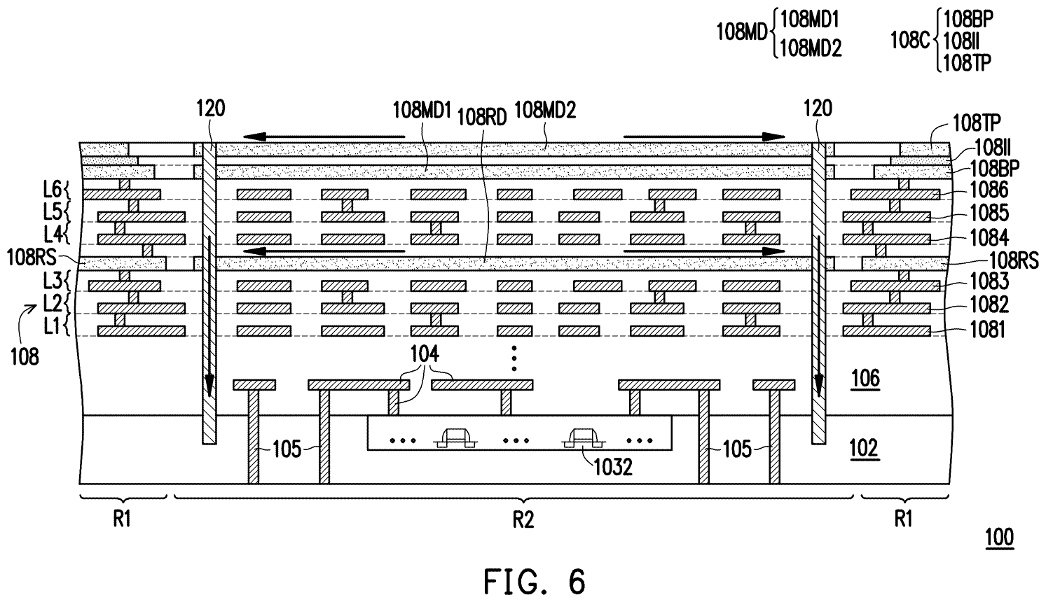

Referring to FIG. 6, in some embodiments, heat pipes 120 are formed in the wafer 100. In some embodiments, as seen in FIG. 6, the heat pipes extend from the top surface of the wafer structure 100 downward, penetrate through the first and second dummy metallic film patterns 108MD1 and 108MD2, the dummy resistive film patterns 108RD, the insulation material 107, the dielectric material 106 into the semiconductor substrate 102. As seen in FIG. 6, the dummy resistive film patterns 108RD and the first and second dummy metallic film patterns 108MD1 and 108MD2 function as thermal traces and are connected by the heat pipes 120 penetrating there-through to establish thermal pathway (heat transfer direction shown in arrows in FIG. 6) for assisting heat transfer from hot spots to the semiconductor substrate 102 and to the surroundings. The formation of the heat pipes 120 involves drilling or etching to form through holes and filling a thermal conductive metal material into the through holes to form the heat pipes 120. In some embodiments, the heat pipes 120 are not connected with metallization structures 108 or other electrical elements (electrical floating) and are not part of the electrical pathway.

Comparing the schematic top views of and FIG. 3 and FIG. 5, the configurations of the dummy resistive film pattern 108RD and the first dummy metallic film pattern 108MD1 are different, the spans of the first dummy metallic film patterns 108MD1 and the dummy resistive film patterns 108RD are at least partially overlapped, even though the locations of the possibly passing through heat pipes are coincided. As the first dummy metallic film patterns 108MD1 (dummy metallic film patterns 108MD) and the dummy resistive film patterns 108RD are located at different levels, their respective designs or configurations may be adjusted based on the distribution and location of the underlying heat generation spots.

Although the steps of the method are illustrated and described as a series of acts or events, it will be appreciated that the illustrated ordering of such acts or events are not to be interpreted in a limiting sense. In addition, not all illustrated process or steps are required to implement one or more embodiments of the present disclosure. Furthermore, whilst the illustrated processes belong to a wafer-on-wafer (WoW) process and may be further fabricated into singulated die units applicable for stacking packages or chip-on-wafer-on-substrate (CoWoS) packages, constructed wafers including multiple chips may be used in the above processes.

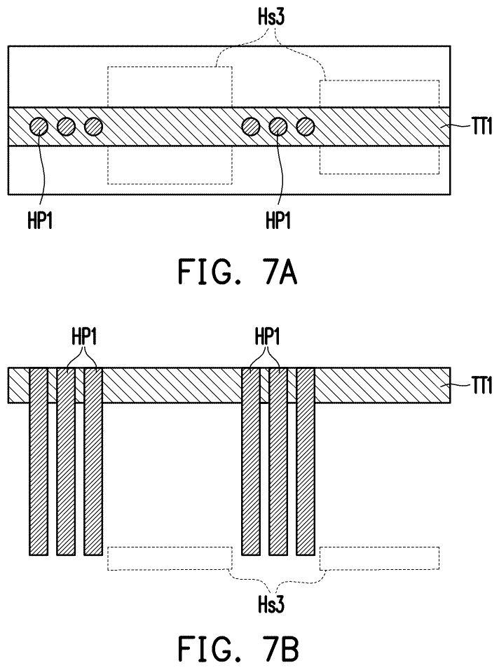

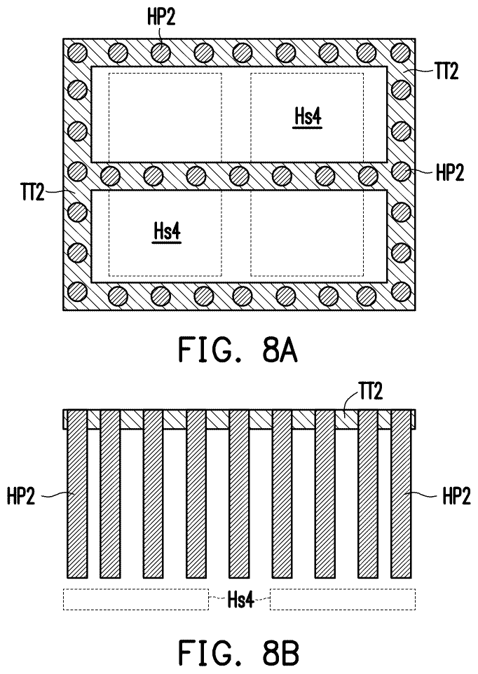

FIG. 7A, FIG. 8A, FIG. 7B and FIG. 8B are schematic top views and cross-sectional views showing the relative arrangement of the thermal trace and the heat pipes relative to the locations of the underlying heat generating spots according to embodiments of the present disclosure.

Referring to FIG. 7A and FIG. 7B, heat pipes HP1 penetrate through the thermal trace TT1 and extend from the thermal trace TT1 downward approaching the heat generating spots Hs3, without directly contacting the heat generating spots Hs3. Referring to FIG. 7A, the thermal trace TT1 is formed as a strip extending horizontally across the spans of the heat generating spots Hs3, while the heat pipes HP1 are arranged beside the spans of the heat generating spots Hs3 or between the spans of the heat generating spots Hs3.

It is understood that the heat pipes are not uniformly distributed all over the local cell area but are arranged around the local hot spots. Comparing with the local cell area, the total area of all the heat pipes arranged around the local hot spots may be about 1.5% of the cell area. Through the thermal traces (including dummy metallic film patterns and dummy resistive film patterns), better horizontal heat transfer rates are provided. Furthermore, through the layout design or the design of the patterns or configurations of the thermal traces, the thermal traces are connected with heat pipes at various locations, which enables a more flexible heat pipe arrangement and achieves a more effective heat dissipation scheme.

Referring to FIG. 8A and FIG. 8B, the thermal trace TT2 is formed as a buckle shaped (connected square rings) from the top view, and the heat pipes HP2 are arranged evenly along the pattern of the thermal trace TT2. In FIG. 8B, the heat pipes HP2 also penetrate through the thermal trace TT2 and extend from the thermal trace TT2 downward approaching the heat generating spots Hs4, without directly contacting the heat generating spots Hs4. Referring to FIG. 8A, the thermal trace TT2 is formed to enclose the heat generating spots Hs4, and the thermal trace TT2 extending horizontally across the spans of the heat generating spots Hs4, while some of the heat pipes HP2 are arranged beside the spans of the heat generating spots Hs4, and some heat pipes HP2 are arranged directly above the heat generating spots Hs4.

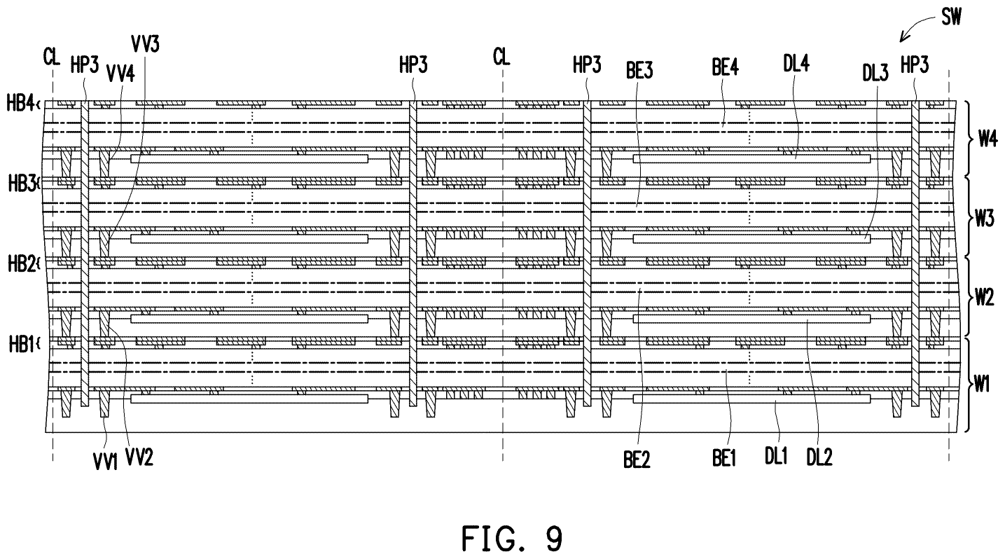

FIG. 9 illustrates a schematic cross-sectional view of an exemplary stacking structure in accordance with some embodiments of the present disclosure.

In some embodiments, referring to FIG. 9, multiple wafers W1, W2, W3 and W4 are stacked in a wafer-on-wafer way to form a wafer-form stacking structure SW. FIG. 9 only shows a portion of the stacking structure SW including at least two die units, and the cutting lanes CL are shown in dashed lines. It is understood that detailed configurations and interlayers may be omitted and represented by the ellipsis dots for simplicity in the figures. For the individual wafer W1, W2, W3 or W4, there is a back-end-of-line zone BE1, BE2, BE3 or BE4 (encircled by dot-dashed lines) located between the device layer DL1, DL2, DL3 or DL4 (formed through front-end-of-line processes) and the bonding structures HB1, HB2, HB3, HB4. In some embodiments, the wafers W1, W2, W3 and W4 are front-to-back bonded through bonding structures HB1, HB2 and HB3. In some embodiments, the wafers W1-W4 are bonded through hybrid interfacial bonding to form the wafer-stacked-on-wafer stacking structure SW. Electrical connection is established between the device layers DL1-DL4 of the wafers W1-W4 through the through semiconductor vias (TSVs) VV1-VV4 and the bonding structures HB1, HB2, HB3. As described in the previous paragraphs, some or all of the wafers W1-W4 are similar to the wafer 100 described in previous paragraphs, and the thermal traces as described above are formed within the back-end-of-line zones BE1, BE2, BE3 and/or BE4 of the wafers W1-W4. Furthermore, heat pipes HP3 are formed in the stacking structure SW, extending through the back-end-of-line zones BE1, BE2, BE3 and BE4 to thermally connect the thermal traces formed in the back-end-of-line zones BE1, BE2, BE3 and/or BE4 to establish a thermal pathway.

In some embodiments, the semiconductor stacking structure may undergo further processing, and global connection structures including redistribution structures and connectors may be formed on the semiconductor stacking structure. Also, the stacking structure may be singulated to form die units or stacking die structures.

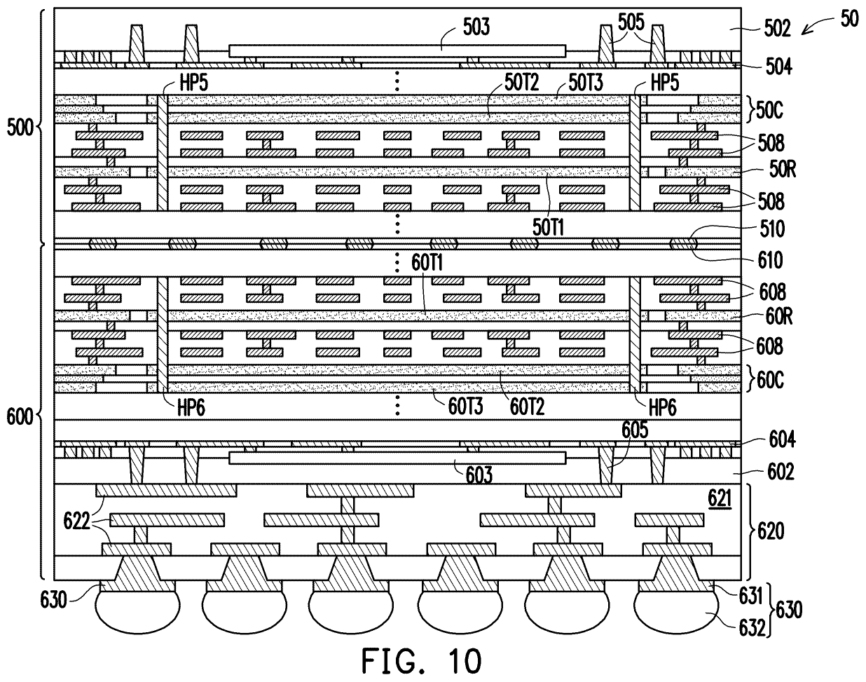

FIG. 10 illustrates a schematic cross-sectional view of an exemplary package structure in accordance with some embodiments of the present disclosure.

Referring to FIG. 10, in some embodiments, the package structure 50 includes a first die 500 stacked on and bonded to a second die 600. In some embodiments, the stacked first and second dies 500 and 600 may be fabricated from the wafer-formed stacking structure SW as described above but with less stacked wafers (e.g. two stacked wafers), with similar elements and configuration design as shown for the wafer 100. It is understood that detailed configurations and interlayers may be omitted and represented by the ellipsis dots for simplicity in the figures. In some embodiments, the first die 500 includes a semiconductor substrate 502, a device layer 503 formed in or on the semiconductor substrate 502, local connection structures 504 connected to the device layer 503, and through vias 505 extending from the local connection structures 504 into the semiconductor substrate 502. In some embodiments, the first die 500 also includes metallization structures 508 and a bonding structure 510. For the first die 500, following the manufacturing method and steps as described for forming the metallization structures 108, the thermal traces 50T1 are formed along with the resistors 50R, and the thermal traces 50T2, 50T3 are formed along with the capacitors 50C. In some embodiments, the thermal traces 50T1 are co-levelled with the resistors 50R, and the thermal traces 50T2, 50T3 are co-levelled with the capacitors 50C. As seen in FIG. 10, the thermal traces 50T1-50T3 sandwiched between the metallization structures 508 are connected by the heat pipes HPS. In some embodiments, the thermal traces 50T1, 50T2, 50T3 are located in the main device region and located above the device layer 503, while the resistors 50R and the capacitors 50C are located in the peripheral region of the die. In certain embodiments, the thermal traces 50T1, 50T2, 50T3 are at least vertically partially overlapped or even fully overlapped. In certain embodiments, the thermal traces 50T1, 50T2, 50T3 are vertically overlapped and vertically aligned in the thickness direction (stacking direction).

In some embodiments, the second die 600 includes a semiconductor substrate 602, a device layer 603, local connection structures 604 connected to the device layer 603, through vias 605, metallization structures 608 and a bonding structure 610. Similarly, the metallization structures 608 may be formed following the manufacturing method and steps as described for forming the metallization structures 108, the thermal traces 60T1 are formed along with the resistors 60R, and the thermal traces 60T2, 60T3 are formed along with the capacitors 60C. In some embodiments, the thermal traces 60T1 are co-levelled with the resistors 60R, and the thermal traces 60T2, 60T3 are co-levelled with the capacitors 60C, and the thermal traces 60T1-60T3 sandwiched between the metallization structures 608 are connected by the heat pipes HP6. In some embodiments, the thermal traces 60T1, 60T2, 60T3 are located in the main device region and located above the device layer 603, while the resistors 60R and the capacitors 60C are located in the peripheral region of the die. In certain embodiments, the thermal traces 60T1, 60T2, 60T3 are at least vertically partially overlapped or even fully overlapped. In certain embodiments, the thermal traces 60T1, 60T2, 60T3 are vertically overlapped and vertically aligned in the thickness direction (stacking direction, shown in arrow).

The thermal traces 50T1-50T3 and 60T1-60T3 are electrically floating and are not electrically connected with the semiconductor devices in the device layers 503 or 603. From FIG. 10, in some embodiments, the thermal traces 50T1-50T3 and 60T1-60T3 are vertically overlapped or vertically aligned. However, it is understood that the thermal traces 50T1-50T3 and the thermal traces 60T1-60T3 of different dies with different layout designs may not vertically overlapped or vertically aligned.

In some embodiments, the first and second dies 500 and 600 have different functions. In some embodiments, the second die 600 includes a logic die, such as central processing unit (CPU) die, graphic processing unit (GPU) die, micro control unit (MCU) die, baseband (BB) die, or application processor (AP) die. In some embodiments, the first die 500 includes a memory die, such as high bandwidth memory (HBM) die, dynamic random access memory (DRAM) die, or static random access memory (SRAM) die.

Referring to FIG. 10, in some embodiments, a redistribution layer (RDL) 620 is formed over the backside of the second die 600, and the RDL 620 is electrically connected to the second die 600 and first die 500 through at least the through vias 605, the metallization structures 608, 508, the bonding structures 610, 510. In some embodiments, the RDL 620 includes redistribution metal patterns 622 embedded in a dielectric material layer 621. The configuration of the redistribution metal patterns is not limited by the disclosure, while the dielectric material layer may include more than one layers of dielectric materials. In certain embodiments, the dielectric material layer 621 exposes some of the underlying redistribution metal patterns 622, and conductive terminals 630 are formed on the exposed metal patterns 622. In some embodiments, the conductive terminal 630 includes a metal post 631 and a bump 632. In some embodiments, the material of the dielectric material layer 621 includes silicon oxide, silicon nitride, low-k dielectric materials, benzocyclobutene (BCB), epoxy, polyimide (PI), or polybenzoxazole (PBO). In some embodiments, a material of the metal post 631 includes copper or cooper alloys, and a material of the bump 632 includes solder. In one embodiment, the metal posts 631 and bumps 632 located on the metal posts 631 constitute micro bumps. In some embodiments, the conductive terminals 630 include copper pillar bumps.

Furthermore, the package structure 50 described above may be further bonded to a circuit substrate or used as package units and fabricated into 3D stacking packages or CoWoS packages, the disclosure is not limited to the package structure shown in the drawings.

In some embodiments, in addition to the metallization structures formed through BEOL processes, additional thermal traces are formed along with the passive devices at the same level using the same material, these thermal traces provide effective horizontal (on the same plane or in-plane) thermal conductivity and achieve better thermal dissipation performance. Further, as the thermal traces are made from the same material layer(s) for forming the passive devices such as resistors and capacitors, no additional costs or minimal costs are required for forming the thermal traces, and a more uniform layout design may be achieved.

Also, by way of forming thermal traces extending horizontally along the plane surfaces, the arrangement of vertically extending heat pipes can be more flexible to establish effective local heat dissipation pathway through the interconnection structures formed by BEOL processes. The existence of the thermal traces effectively promotes heat dissipating from local hot spots and mitigates possible degradation caused by local heat accumulation for the semiconductor stacking structures.

In some embodiments of the present disclosure, a semiconductor structure is provided. The semiconductor structure includes a semiconductor die having a first region and a second region located by the first region. The semiconductor die includes a device layer located in the second region, an insulation material, located over the device layer and extending over the first and second regions, and metallization structures, embedded in the insulation material and electrically connected with the device layer. The metallization structures include passive device structures located in the first region and thermal traces located in the second region, and the passive device structures and the thermal traces include a same material and are located at a same level of the metallization structures, the passive device structures are electrically connected with the device layer, and the thermal traces are electrically floating.

In some embodiments of the present disclosure, a semiconductor structure is provided. The semiconductor structure includes a first die having a first device region and a first peripheral region located beside the first device region, and a second die stacked on and bonded with the first die. The second die has a second device region and a second peripheral region located beside the second device region. The first die includes a first insulation material located above and extending over the first device region and the first peripheral region, and first metallization structures embedded in the first insulating material. The first metallization structures include a resistor structure located in the first peripheral region and a first thermal trace located in the first device region at a same level in the first metallization structures, the resistor structure and the first thermal trace are made of a first metallic material, the first metallic material is different from a material of the first metallization structures, and the first thermal trace has a thermal conductivity higher than that of the first insulation material. The second die includes a second insulation material located above and extending over the second device region and the second peripheral region, and second metallization structures embedded in the second insulating material. The second metallization structures include a capacitor structure located in the second peripheral region and second thermal traces located in the second device region at a same level in the second metallization structures, the capacitor structure and the second thermal traces are made of a second metallic material, the second metallic material is different from a material of the second metallization structures, and the second thermal traces have a thermal conductivity higher than that of the second insulation material.

In some embodiments of the present disclosure, a method for forming a semiconductor structure is described. A first wafer having first dies, each first die having a first device region and a first peripheral region by the first device region, is provided. The first die includes first metallization structures embedded in a first insulation material, wherein the first metallization structures include a resistor structure located in the first peripheral region and a first thermal trace located in the first device region at a same level in the first metallization structures, the resistor structure and the first thermal trace are made of a first metallic material, the first metallic material is different from a material of the first metallization structures, and the first thermal trace has a thermal conductivity higher than that of the first insulation material. A second wafer having second dies, each second die having a second device region and a second peripheral region by the second device region, is provided. The second die includes second metallization structures embedded in a second insulation material, wherein the second metallization structures include a capacitor structure located in the second peripheral region and second thermal traces located in the second device region at a same level in the second metallization structures, the capacitor structure and the second thermal traces are made of a second metallic material, the second metallic material is different from a material of the second metallization structures, and the second thermal traces have a thermal conductivity higher than that of the second insulation material. The first wafer and the second wafer are bonded through the first and second bonding structures to form a semiconductor structure.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method for forming a semiconductor structure, comprising:
providing a first wafer having a first semiconductor substrate and a first device layer formed therein;
forming a first insulation material over the first semiconductor substrate and forming first metallization structures embedded in the first insulation material, wherein forming the first metallization structures includes forming a first resistor structure and a first thermal trace at a same level of the first metallization structures, and the first thermal trace has a thermal conductivity higher than that of the first insulation material;
forming a second insulation material over the first insulation material and forming second metallization structures embedded in the second insulation material, wherein forming the second metallization structures include forming a first capacitor structure and second thermal traces at a same level of the second metallization structures, wherein the second thermal traces have a thermal conductivity higher than that of the second insulation material; and
forming heat pipes extending through the first and second thermal traces and extending into the first semiconductor substrate.

2. The method of claim 1, further comprising:
providing a second wafer having a second semiconductor substrate and a second device layer formed therein; and
bonding the first wafer and the second wafer through bonding structures.

3. The method of claim 2, further comprising:
forming a third insulation material over the second semiconductor substrate and forming third metallization structures embedded in the third insulation material, wherein forming the third metallization structures includes forming a second resistor structure and a third thermal trace at a same level of the third metallization structures, and the third thermal trace has a thermal conductivity higher than that of the third insulation material; and
forming a fourth insulation material over the third insulation material and forming fourth metallization structures embedded in the fourth insulation material, wherein forming the fourth metallization structures include forming a second capacitor structure and fourth thermal traces at a same level of the second metallization structures, wherein the fourth thermal traces have a thermal conductivity higher than that of the fourth insulation material, after providing the second wafer and before bonding the first and second wafers.

4. The method of claim 3, wherein the heat pipes are formed after bonding the first and second wafers, and the heat pipes extend through the third and fourth thermal traces as well as the first and second thermal traces.

5. The method of claim 2, further comprising performing a singulation process to cut through the bonded first and second wafers to form individual stacked dies.

6. The method of claim 1, wherein the first resistor structure and the first thermal trace are made of a first metallic material, the first metallic material has an electrical resistivity higher than a material of the first metallization structures.

7. The method of claim 3, wherein the second resistor structure and the third thermal trace are made of a second metallic material, the second metallic material has an electrical resistivity higher than a material of the third metallization structures.

8. The method of claim 1, wherein the first thermal trace is electrically isolated from the first resistor structure by the first insulation material, and the second thermal traces are electrically isolated from the first capacitor structure by the second insulation material.

9. The method of claim 3, wherein the third thermal trace is electrically isolated from the second resistor structure by the third insulation material, and the fourth thermal traces are electrically isolated from the second capacitor structure by the fourth insulation material.

10. The method of claim 1, wherein forming heat pipes includes forming through holes by drilling or etching, and filling a thermal conductive metal material into the through holes to form the heat pipes, and the heat pipes are electrically isolated from the first and second metallization structures.

11. A method for forming a semiconductor structure, comprising:
providing a first wafer having a first semiconductor substrate, a first insulation material over the first semiconductor substrate, and first metallization structures embedded in the first insulation material, wherein the first metallization structures include a first resistor structure and a first thermal trace made of a first metallic material and at a same level in the first metallization structures;
providing a second wafer having a second semiconductor substrate, a second insulation material over the second semiconductor substrate, and second metallization structures embedded in the second insulation material, wherein the second metallization structures include a first capacitor structure and second thermal traces made of a second metallic material and at a same level in the second metallization structures;
bonding the first wafer and the second wafer to form a semiconductor structure; and
forming heat pipelines extending through the first and second thermal traces and extending into the first semiconductor substrate.

12. The method of claim 11, further comprising:
providing a third wafer having a third semiconductor substrate, a third insulation material over the third semiconductor substrate, and third metallization structures embedded in the third insulation material, wherein the third metallization structures include a second resistor structure and a third thermal trace made of a third metallic material and at a same level in the third metallization structures; and
bonding the third wafer to the second wafer, wherein the heat pipelines are formed after bonding the third wafer to the second wafer, and the heat pipes extend through the first, second and third thermal traces.

13. The method of claim 12, further comprising:
providing a fourth wafer having a fourth semiconductor substrate, a fourth insulation material over the fourth semiconductor substrate, and fourth metallization structures embedded in the fourth insulation material, wherein the fourth metallization structures include a second capacitor structure and fourth thermal traces made of a fourth metallic material and at a same level in the fourth metallization structures; and
bonding the fourth wafer to the third wafer, wherein the heat pipelines are formed after bonding the fourth wafer to the third wafer, and the heat pipes extend through the, first, second, third and fourth thermal traces.

14. The method of claim 11, further comprising performing a singulation process to form individual stacked dies.

15. The method of claim 11, wherein the first metallic material has an electrical resistivity higher than that of the first metallization structures, the first thermal trace is electrically isolated from the first resistor structure by the first insulation material, and the second thermal traces are electrically isolated from the first capacitor structure by the second insulation material.

16. The method of claim 13, wherein the third metallic material has an electrical resistivity higher than that of the third metallization structures, the third thermal trace is electrically isolated from the second resistor structure by the third insulation material, and the fourth thermal traces are electrically isolated from the second capacitor structure by the fourth insulation material.

17. A method, comprising:
providing a first wafer having a first substrate with a first device region and a first peripheral region beside the first device region;
forming a first insulation material over the first substrate, and forming a first thermal trace in the first device region and forming a first resistor structure in the first peripheral region at a same level in a same process on the first insulation material, the first resistor structure and the first thermal trace are made of a first metallic material, and the first thermal trace has a thermal conductivity higher than that of the first insulation material;
forming a second insulation material over the first substrate, and forming second thermal traces in the first device region and forming a first capacitor structure in the first peripheral region at a same level in a same process over the second insulation material, the first capacitor structure and the second thermal traces are made of a second metallic material, and the second thermal traces have a thermal conductivity higher than that of the second insulation material; and
forming heat pipes extending through the first and second thermal traces and extending into the first substrate.

18. The method of claim 17, further comprising providing a second wafer having a second device region and a second peripheral region by the second device region, wherein providing the second wafer includes forming a third insulation material, and forming a second capacitor structure in the second peripheral region and third thermal traces in the second device region at a same level in the same process on the third insulation material, the second capacitor structure and the third thermal traces are made of a third metallic material, and the third thermal traces have a thermal conductivity higher than that of the third insulation material; and bonding the second wafer and the first wafer to form a semiconductor stack structure.

19. The method of claim 18, wherein providing the second wafer includes forming a fourth insulation material, and forming a fourth thermal trace in the second device region and forming a second resistor structure in the second peripheral region at a same level in a same process on the fourth insulation material, the second resistor structure and the fourth thermal trace are made of a fourth metallic material, and the fourth thermal trace has a thermal conductivity higher than that of the fourth insulation material.

20. The method of claim 9, wherein the first thermal trace and the fourth thermal trace are electrically isolated from the first resistor structure and second resistor structure respectively, and the second thermal traces and the third thermal traces are electrically isolated from the first capacitor structure and the second capacitor structure respectively.
